(19) United States
(12) Patent Application Publication
(10) Pub. No.: US 2017/0168131 A1
(43) Pub. Date: Jun. 15, 2017

(54) METHOD FOR MONITORING CURRENT SENSORS

(71) Applicant: Robert Bosch GmbH, Stuttgart (DE)

(72) Inventors: Joerg Schneider, Stuttgart (DE); Florian Follath, Ludwigsburg (DE)

(21) Appl. No.: 15/309,058

(22) PCT Filed: Apr. 9, 2015
(86) PCT No.: PCT/EP2015/057677

§ 371 Date: Nov. 4, 2016

(30) Foreign Application Priority Data
May 8, 2014 (DE) 10 2014 208 680.9

(51) Int. Cl. G01R 35/00; G01R 19/10; B60L 3/00; G01R 31/36

(52) U.S. Cl. CPC G01R 35/00; G01R 31/3655; G01R 19/10; B60L 3/0038

(57) ABSTRACT

This invention relates to a method for monitoring current sensors (7), (8), (9) during the determining of a total electric current, I, from a battery, preferably from a lithium-ion battery, in an electrical circuit (1) having current sensors (7), (8) in a parallel conductor section (3) with at least two parallel conduction paths (5), (6), for determining the respective current components I₁, I₂. According to the invention, the electric circuit (1) has a further current sensor (9) for determining the total current I. In a scaling step, scaling factors S₁, S₂ are defined, by the use of which current components I₁, I₂ flowing in the parallel conduction paths (5), (6) can be scaled up to the total current, I. In a monitoring step, measured current components I_{M1}, I_{M2} are scaled up by means of scaling factors S₁, S₂ and thus calculated total currents I_{B1} (10), I_{B2} (11) are defined and compared with one another and with a total current I_{M} (12) determined by the current sensor (9). The invention further relates to a battery system with a control device configured to perform such a method.

### BACKGROUND OF THE INVENTION

The invention relates to a method for monitoring current sensors when determining a current delivered by a battery.

Battery systems are increasingly used as energy stores for stationary as well as mobile applications. Wind turbines and emergency power systems represent examples of a stationary application, and electric and hybrid vehicles represent a mobile application. In the case of such applications, very high demands are placed on the battery system with regard to reliability, power, service life and safety.

In this regard, battery systems are frequently used which are based on lithium-ion battery cells. To this end, a multiplicity of battery cells is generally connected in series to form battery modules. A plurality of battery modules is in turn joined together to form a battery system by means of a series or parallel circuit, which battery system is also referred to below as a battery.

In order to be able to meet the aforementioned demands placed on a battery, a battery requires an effective battery management system which monitors the functional parameters of the individual battery cells. A battery management system monitors and controls inter alia the voltages of the individual cells, monitors the charge states as well as the temperatures and protects the individual battery cells from overload. In so doing, it is very important for the measuring data provided to the battery management system to be reliable. A current sensor, which, for example, transmits a load current to the battery management system that has erroneously been determined too low, can, for example, lead to false reactions of the battery management system and thus to harmful overloads on the battery.

It is furthermore very important for batteries used in a mobile application, in particular vehicle batteries, that the amount of energy extracted via the discharge current of the battery be reliably and precisely detected in order, for example, to calculate the remaining cruising range. In addition, too high of a discharge current can endanger the thermal stability of the battery and thus lead to a risk of explosion. If the discharge current of a vehicle battery cannot be reliably determined, the international standard ISO 26262 requires the battery current to be interrupted, which, especially in a battery operated vehicle leads to a complete breakdown of the drivetrain.

The German patent application DE 10 2011 080 603 A1 describes a method for measuring electric current in a circuit comprising a battery. In this case, the current is divided in an electrical circuit into two paths, a means for measuring current being provided for each path. A plausibility check can be performed by recently determined values being compared with values previously determined.

The German patent application DE 102 12 685 A1 describes a circuit arrangement and a method, with which an electric circuit can be checked to see if it is operating correctly. In so doing, a first and a second current sensor are provided in an electric circuit.

The German patent application DE 10 2012 212 367 A1 describes a device for measuring an electric current between a vehicle battery and an electric load connected to the vehicle battery.

### SUMMARY OF THE INVENTION

The subject matter of the invention is a method for monitoring current sensors when determining a total electric current I from a battery, preferably from a lithium-ion battery, in an electrical circuit, wherein the electrical circuit comprises a total conductor section and a parallel conductor section connected in series with the total conductor section, the total conductor section having a total conductor line and the parallel conductor section having at least two parallel conduction paths, wherein a total current I flows in the total conductor line and a current component I₁, I₂ flows in each case in the at least two parallel conduction paths, the at least two conduction paths each having a current sensor for determining the respective current component I₁, I₂, characterized in that the electrical circuit has a current sensor for determining the total current I in the total conductor line and

a) in a scaling step

an associated scaling factor S₁, S₂ is defined in each case for the conduction paths, said scaling factor describing the inverse ratio of the respective current component I₁, I₂ in the respective conduction path to the total current I in the total conductor line, and

b) in a monitoring step

b1) current components I_{M1}, I_{M2} measured by the current sensors in the respective conduction paths are determined,

b2) a measured total current I_{M} is determined by means of the current sensor in the total conductor line,

b3) a calculated total current I_{B1}, I_{B2} is calculated in each case by means of the respective links between the measured current components I_{M1}, I_{M2} and the associated scaling factors S₁, S₂, and

b4) the calculated total currents I_{B1}, I_{B2} are compared with one another as well in each case with the measured total current I_{M} in order to monitor the current sensors.

The advantage of this method is in the formation of a redundancy, the formation of the redundancy not only being suitable for recognizing the presence of a fault but also additionally under certain circumstances being suitable for localizing a fault. Furthermore, this method is suitable for tolerating a defective current sensor under certain circumstances, i.e. facilitating a reliable determination of the total current despite the breakdown of a current sensor. This has in turn the advantage that the battery system can be further operated despite a defective current sensor. In the case of a purely battery operated vehicle, a breakdown of the drivetrain can be avoided.

The respective scaling factors S₁, S₂ are defined in a first step a) in such a way that said factors describe the inversely proportional value of a current component I₁, I₂ in a connection path in relation to a corresponding total current I. In other words, the scaling factors S₁, S₂ are defined inversely proportional to the current components in the conduction paths in relation to the total conductor line. If a total current I is uniformly divided between N conduction paths, a current component I₁, 1₂ in the amount of 1/N of the total current then flows in each conduction path. The value N is assigned to the scaling factors in this case.

The scaling factors S₁, S₂ are advantageously defined onetime, for example during the startup operations of the electric circuit. At the point in time of the startup operations, in particular an initial start-up, the electric components do not have any signs of ageing, so that said components should have the specified electrical properties thereof. The scaling factors S₁, S₂ are advantageously stored. As a result, it can subsequently be assumed that a given current divider ratio does not change pursuant to the resistance ratios of the connection paths among themselves. The scaling factors S₁, S₂ are advantageously redefined after a change in the current divider ratio.

In order to determine the calculated total currents I_{B1}, I_{B2} in step b3), the current components I_{M1}, _{M2} determined in step b1) by the current sensors for detecting the current components I₁, I₂ in the respective conduction paths are linked with the respective scaling factors S₁, S₂. If the scaling factors S₁, S₂ were defined by means of the inverse relationship of the respective current component I₁, I₂ in the respective conduction path to the total current I in the total conductor line, the linking takes place in the form of a multiplication, I_{B1}=S₁*I_{M1}, or respectively I_{B2}=S₂*I_{M2}.

In step b4), the values calculated in step b3) for the total current I_{B1}, I_{B2} are compared with a total current I_{M} measured in step b2) via the current sensor for determining the total current I. In addition, the calculated currents I_{B1}, I_{B2} are compared with one another, so that in total N*(N+1)/2 comparisons take place in a circuit having N conduction paths.

The calculated total currents I_{B1}, I_{B2} are advantageously compared with one another as well as with the measured total current I_{M} by the amount of a difference between the calculated total currents I_{B1}, I_{B2} among themselves and between the respective calculated total currents I_{B1}, I_{B2} and the measured total current I_{M} being determined. In so doing, two compared currents I_{B1}, I_{B2} are considered to be equally high in each case if the respective difference lies below a predeterminable maximum value. Because the currents in the total conductor line as well as in the conduction paths are constant during the operation of the electrical circuit, the difference formation constitutes a simple option of a relative comparison. A predeterminable maximum value can correspond to a maximally tolerable tolerance value. A threshold value comparison having a predeterminable maximum value offers the option of a simple check whether the deviation of the measurement values among themselves lies under a tolerance value.

In a circuit according to the invention having, for example, two conduction paths, for which respectively one scaling factor S₁, S₂ was determined at 2.0, for example, in each case in step a), the result of a determination of the current components according to step b1) can lead to the determined current components I_{M1}=25.0 A and I_{M2}=25.4 A. When linking the scaling factors S₁ and S₂ with the determined current components I_{M1}, I_{M2}, the calculated total currents are I_{B1}=2.0*25.0 A and I_{B2}=2.0*25.4 A according to step b3). If, in step b2), a total current of I_{M}=50.0 A was determined, the calculated total currents I_{B1}=50.0 A and I_{B2}=50.8 A are compared with one another as well as with the determined total current I_{M}=50.0 A.

The comparison takes place advantageously by means of an amount-related calculation of the differences between the currents. The amount of the differences I_{B1}−I_{B2} and I_{B2}−I_{M} is in this example 0.8 A in each case; the amount of the difference I_{B1}−I_{M} is 0 A. The determined currents are considered to be equally high, provided the determined differences do not exceed a predeterminable maximum value. If the predeterminable maximum value is specified at 1.0 A, the currents determined by the current sensors are then considered to be equally high.

If the parallel conductor section has exactly two parallel conduction paths as in the previous example, the monitoring is advantageously performed in such a way that no or one positive control message is emitted if the two calculated total currents I_{B1}, I_{B2} and the measured total current I_{M} are considered to be equally high. If one of the compared currents deviates from at least one other compared current, a warning message is advantageously emitted. If all of the compared currents are considered not to be equally high, an error message is advantageously emitted and/or the total current I is interrupted in the total conductor line by an interruption device.

In regard to the previous example, this means that the currents I_{B1}, I_{B2} and I_{M} are no longer considered to be equally high at a predeterminable maximum value of, for example, 0.5 A because the amount of the differences I_{B1}−I_{B2} and I_{B2}−I_{M} exceed the value of 0.5 A. The currents I_{B1} and I_{M} are however considered to be equally high because the amount of the difference between them I_{B1}−I_{M} lies below the maximum value of 0.5 A. Because the condition that at least one of the compared currents deviates from at least one other compared current is fulfilled, a warning message is advantageously emitted. An error message and/or an interruption of the total current does not occur in this example because not all of the compared currents are considered to be of a different magnitude. Two of the current sensors have determined two measured values that are comparable to one another after scaling so that the conclusion can be drawn in the sense of a majority decision that the third current sensor has determined erroneous measured values due to the fact that a value was determined for the total current that deviates from the other measured or determined total currents.

This example makes clear that such an embodiment of the invention advantageously facilitates a further operation of the electrical circuit provided only one current sensor does not deliver any measured values or delivers erroneous measured values. Particularly during the operation of a battery operated vehicle, this has the advantage that the error or breakdown of a current sensor does not lead to the breakdown of the vehicle powertrain.

The method can be advantageously carried out in such a way that step a) occurs once, for example during an initial start-up of the electrical circuit and that step b) is repeated during each renewed start-up of the electrical circuit or continually during the operation of the electrical circuit.

The scaling factors S₁, S₂ are advantageously determined in step a) via measurements in such a way that a scaling current flows in the total conductor line of the total conductor section, said scaling current being divided in the parallel conductor section between at least two scaling current components in the at least two conduction paths that are connected in parallel, and the measurements are performed via the current sensors for determining the current components I₁, I₂ and the current sensor for determining the total current I.

In other words, that means that the scaling factors are determined on the basis of measured values which are determined by the current sensors to be monitored themselves. The advantage of this embodiment is that no additional means for determining the currents are required and the measured values are not distorted by such additional means for measurement. The risk that already erroneous measurements lead to a false scaling in such an approach can be reduced by the current sensors being checked prior to an initial start-up of the electrical circuit and/or by the determined scaling factors being put to a plausibility test.

When determining the scaling factors S₁, S₂, the amount of the scaling current in the total conductor line is advantageously at least a value that is representative for the operation of the electrical circuit. The amount of the scaling current in the total conductor line is advantageously at least 50 ampere when determining the scaling factors S₁, S₂. A current of this magnitude roughly corresponds to the total current which occurs in a vehicle during an operation of the method. A scaling below a value representative for the operation has the advantage that the effect of possible non-linear effects is minimized when dividing the total current into current components.

In the scaling step a), a scaling error is advantageously defined, wherein the scaling error is determined as the amount of a difference between a scaling current measured in the total conductor line and the sum of scaling current components measured in the at least two conduction paths connected in parallel and wherein the scaling factors S₁, S₂ are only calculated as long as the scaling error lies below an adjustable scaling tolerance, preferably 1 ampere.

Such an embodiment of the invention has the advantage that a defective current sensor can be recognized when carrying out the scaling step. The value of the scaling tolerance describes a reliable scaling error. An adjustable scaling tolerance has the advantage that scaling errors differing in magnitude can be allowed depending on the quality of the current sensors and/or the requirements of a respective application for the accuracy of the current measurement.

The current sensors for measuring a current component I₁, I₂ in a conduction path advantageously comprise a shunt. Such a configuration has the advantage that the current divider ratio of the conduction paths among themselves can be adjusted via the shunts of the conduction paths. The resistance value of a shunt generally significantly exceeds the resistance value of the line as well as that of further components that, as the case may be, are present in a conduction path, so that the resistance value of a conduction path can substantially be described by the resistance value of the shunt. The current divider ratio and thus the division of the total current I into the current components I₁, I₂ can consequently be advantageously defined by the shunts.

In addition, the current sensor advantageously has a Hall sensor for determining the total current I in the total conductor line. Such a configuration has the advantage that a shunt is not required to determine the total current I, via which shunt a portion of the electrical power extracted from the battery in the form of heat would be lost.

The method is advantageously carried out in a battery system, wherein the battery system is connected to a battery, preferably a lithium-ion battery, and to an electrical circuit. In this case, the electrical circuit has a total conductor section and a parallel conductor section connected in series to the total conductor section, and the total conductor section has a total conductor line and the parallel conductor section has at least two parallel conduction paths, wherein the at least two parallel conduction paths have in each a current sensor for determining the current components I₁, 1₂. The invention is characterized in that the battery system has a current sensor in the total conductor line for determining a total current I that can be delivered by the battery, wherein a control device is furthermore provided, which is equipped to carry out a method. Such a battery system has the advantage that a fault or a breakdown of a current sensor does not have to lead to an interruption of the battery current. Furthermore, a battery operated motor vehicle advantageously has such a battery system. A motor vehicle having a battery system which is operated according to the inventive method has the advantage that the fault or breakdown of a current sensor does not lead to the breakdown of the vehicle powertrain.

### BRIEF DESCRIPTION OF THE DRAWINGS

Further advantages and advantageous configurations of the subject matters according to the invention are illustrated by the drawings and explained in the following description. It should be noted that the drawings have only a descriptive character and are not intended to restrict the invention in any form. In the drawings:

FIG. 1 shows a configuration of an electrical circuit, which has current sensors for determining a total current flowing through the circuit; and

FIG. 2 shows a schematic depiction of the comparison of the currents determined by the method.

### DETAILED DESCRIPTION

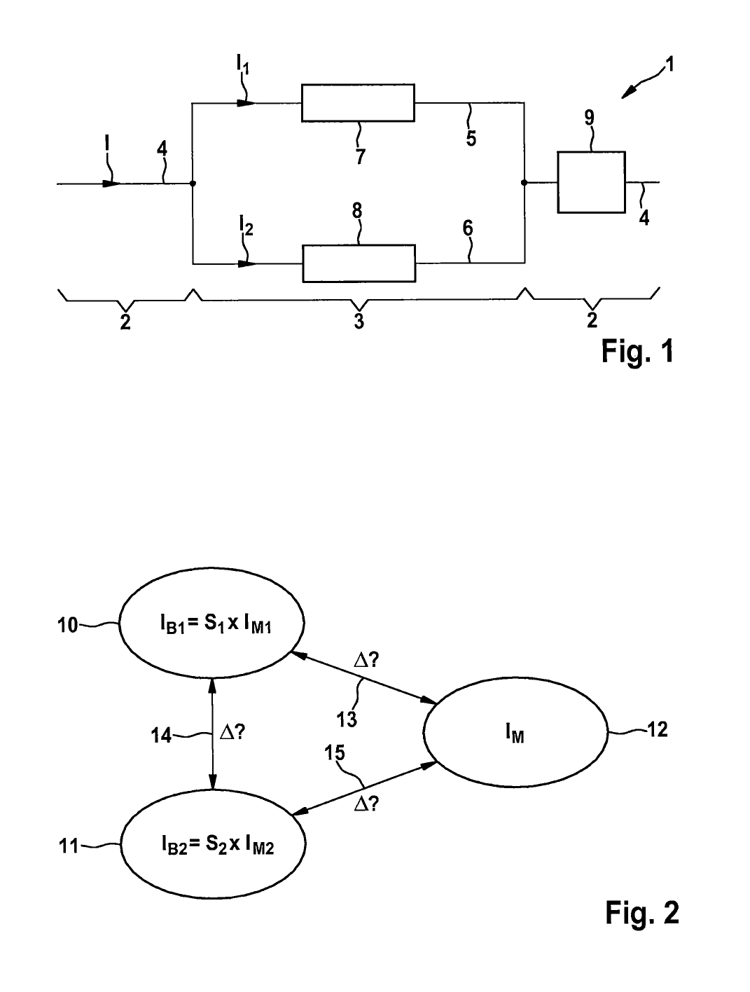

FIG. 1 shows an electrical circuit 1, which has current sensors 7, 8, 9 for determining a total current I flowing through the circuit and by means of which the method according to the invention can be carried out by way of example. The total current I is provided by a battery that is not shown here and is preferably embodied as a lithium-ion battery.

The electrical circuit 1 has a total conductor section 2 and a parallel conductor section 3 connected in series to the total conductor section 2, wherein the total conductor section 2 has a total conductor line 4 and the parallel conductor section 3 has at least two parallel conduction paths 5, 6. A total current I flows in the total conductor line 4 and respectively one current component I₁, I₂ flows in the at least two parallel conduction paths 5, 6. In addition, the at least two conduction paths 5, 6 have in each case a current sensor 7, 8 for determining the respective current component I₁, I₂. Furthermore, the electrical circuit 1 has a current sensor 9 for determining the total current I in the total conductor line 4.

In an advantageous embodiment of the method, an associated scaling factor S₁, S₂ is defined in each case for the conduction paths 5, 6 in a scaling step a), said scaling factor describing the inverse relationship of the respective current component I₁, I₂ in the respective conduction path 5, 6 to the total current I in the total conductor line 4. In so doing, the scaling current is, for example, 50 A. The current sensors 7, 8 have in each case a shunt having a resistance value R_{S1} or respectively R_{S2}. These resistance values are large with respect to the resistance value of the lines in the conduction paths 5 and 6 so that the resistance value of the conduction paths 5 and 6 can be described by the resistance values of the shunts R_{S1} or respectively R_{S2}. The scaling current divides itself up just as the total current I into the two conduction paths 5 and 6, wherein the current divider ratio is described by the resistance values of the shunts. In accordance with the resistance values, the scaling current or respectively total current I is divided according to the current divider rule to I₁=I*R_{S2}/(R_{S1}+R_{S2}) and I₂=I* R_{S1}/(R_{S1}+R_{S2}). If, for example, both resistance values R_{S1} and R_{S2} are equally high, the scaling current or respectively total current I is divided in each case equally between both conduction paths 5 and 6, i.e. at a scaling current of 50 A to 25 A in each case.

The scaling advantageously takes place during an initial start-up with tested current sensors 7, 8, 9, which should in each case correctly determine the values of the current components I₁, I₂ of respectively 25 A as well as the value of total current I of 50 A.

In order to verify the plausibility of the determined measured values, a scaling error is initially determined via the difference between the scaling current of 50 A measured in the total conductor line 4 and the sum of scaling current components, each 25 A, measured in the two connection paths 5, 6 that are connected in parallel. This is 50 A−(25 A+25 A)=0 A in this example.

Because this scaling error of 0 A lies below an adjustable scaling tolerance of, for example, 1 A, the scaling factors are defined according to the scaling step a) to be S₁=I/I₁=50/25 and S₂=I/I₂=50/25, i.e to be 2 in each case.

In addition, provided the resistance values of the shunts are known, a plausibility check of the calculated scaling factors is possible by means of a comparison with the current divider ratio resulting from the resistance ratios. The scaling factors calculate accordingly to: S₁=I/I₁=I/(I*R_{S2}/(R_{S1}+R_{S2}))=(R_{S1}+R_{S2})/R_{S2}, or respectively S₂=(R_{S1}+R_{S2})/R_{S1}.

When carrying out the monitoring step b) the current components I_{M1}, I_{M2} are measured by means of the current sensors 7, 8 for determining the current components I₁, I₂ in the respective conductive paths 5, 6. A measured total current I_{M} 12 in the total conductor line 4 is measured via the current sensor 9 for determining the total current I, and a calculated total current I_{B1} 10, I_{B2} 11 is calculated in each case by means of respective links of the measured current components I_{M1}, I_{M2} with the associated scaling factors S₁, S₂.

In order to monitor the current sensors 7, 8 for determining the current components I₁, I₂ and the current sensor 9 for determining the total current I, the calculated total currents I_{B1} 10, I_{B2} 11 are compared with one another as well as in each case with the measured total current I_{M} 12, as can be seen in FIG. 2.

If the current components I_{M1} and I_{M2} are determined to be I_{M1}=25.0 A and I_{M2}=25.4 A, the calculated total currents I_{B1} 10 and I_{B1} 11 are then determined to be I_{B1}=S₁*I_{M1}=2.0*25.0=50 A and I_{B2}=S₂=2.0*25.4 A=50.8 A. These are compared with one another as well as with the determined total current I_{M} 12, I_{M}=50.0 A/.

The comparison takes place by means of an amount-related calculation of the differences 13, 14, 15 between the currents I_{B1} 10, I_{B2} 11 and I_{M} 12. The amount of the difference 14 I_{B1}−I_{B2} and the difference 15 I_{B2}−I_{M} is in this example in each case 0.8 A; the amount of the difference 13 I_{B1}−I_{M} is 0 A. The determined currents 10, 11, 12 are considered equally high because the determined differences 13, 14, 15 do not exceed a predetermined maximum value of 1.0 A.

If the predeterminable maximum value is however smaller, for example predetermined to be 0.5 A, the currents I_{B1} 10, I_{B2} 11 and I_{M} 12 are no longer considered to be equally high because the amount of the difference 14 I_{B1}−I_{B2} and of the difference 15 I_{B2}−I_{M} exceeds the value of 0.5 A. The currents I_{B1} 10 and I_{M} 12 are however considered to be equally high because the amount of the difference 13 thereof I_{B1}−I_{M} lies below the maximum value of 0.5 A. Because the condition, that at least one of the compared currents I_{B1} 10, I_{B2} 11 and I_{M} 12 deviates from at least one further compared current I_{B1} 10, I_{B2} 11 and I_{M} 12, is fulfilled, a warning message is emitted. An error message and/or an interruption of the total current I does not take place because not all compared currents 10, 11, 12 are considered to be of different magnitude. Two of the current sensors 7, 8, 9 have determined two measured values that are comparable to each other after scaling so that the conclusion can be drawn in the sense of a majority decision that the third current sensor 8 has determined a faulty measurement value due to the fact that a value for the total current was determined that deviates from the other measured or determined total currents 10, 11, 12.

1. A method for monitoring current sensors (7), (8), (9) when determining a total electric current I from a battery in an electrical circuit (1), said electrical circuit (1) having a total conductor section (2) and a parallel conductor section (3) connected in series with the total conductor section (2), wherein the total conductor section (2) has a total conductor line (4) and the parallel conductor section (3) has at least two parallel conduction paths (5), (6), the total current I flowing in the total conductor line (4) and respectively one current component I₁, I₂ flowing in each of the at least two parallel conduction paths (5), (6), wherein the at least two conduction paths (5), (6) have in each case a current sensor (7), (8) for determining the respective current components I₁, I₂, characterized in that the electrical circuit (1) has a current sensor (9) for determining the total current I in the total conductor line (4), and
a) in a scaling step
defining an associated scaling factor S₁, S₂ in each case for the conduction paths (5), (6), said scaling factor describing an inverse relationship of the respective current component I₁, I₂ in the respective conduction path (5), (6) to the total current I in the total conductor line (4), and
b) in a monitoring step
b1) measuring current components I_{M1}, I_{M2} by current sensors (7), (8) in the respective conduction paths (5), (6)
b2) determining a measured total current I_{M} (12) by the current sensor (9) in the total conductor line (4),
b3) calculating a total current I_{B1} (10), I_{B2} (11) of the respective links of the measured current components I_{M1}, I_{M2} using the associated scaling factors S₁, S₂, and
b4) comparing the calculated total currents I_{B1} (10), 1_{B2} (11) with one another as well as in each case with the measured total current I_{M} (12) in order to monitor the current sensors (7), (8), (9).

2. The method according to claim 1, characterized in that the calculated total currents I_{B1} (10), I_{B2} (11) are compared with one another as well as with the measured total current I_{M} (12) by the amount of a difference (13), (14), (15) being determined between the calculated total currents I_{B1} (10), I_{B2} (11) with one another and between the respective calculated total currents I_{B1} (10), I_{B2} (11) and the measured total current I_{M} (12); and in that respectively two of the compared currents I_{B1} (10), I_{B2} (11), I_{M} (12) are considered to be equally high if the respective difference (13), (14), (15) lies below a predeterminable maximum value.

3. The method according to claim 2, characterized in that the parallel conductor section (3) has exactly two parallel conduction paths (5), (6) and the monitoring takes place in such a way that no or a positive control message is emitted if the two calculated total currents I_{B1} (10), I_{B2} (11) and the measured total current I_{M} (12) are considered to be equally high, and/or that a warning message is emitted -if one of the compared currents I_{B1} (10), I_{B2} (11), I_{M} (12) deviates from at least one further compared current I_{B1} (10), I_{B2} (11), I_{M} (12), and/or that the total current I in the total conductor line (4) is interrupted by an interruption device and/or an error message is emitted if all of the compared currents I_{B1} (10), I_{B2} (11), I_{M} (12) are not considered to be equally high.

4. The method according to claim 1, characterized in that the scaling factors S₁, S₂ are defined via measurements such that a scaling current flows in the total conductor line (4) of the total conductor section (2), said scaling current being divided in the parallel conductor section (3) into at least two scaling current components in the at least two conduction paths (5), (6) that are connected in parallel, and the measurements take place by the current sensors (7), (8), (9).

5. The method according to claim 4, characterized in that the amount of the scaling current in the total conductor line (4) is at least 50 amperes.

6. The method according to claim 4, characterized in that a scaling error is defined in the scaling step, said scaling error being determined as the amount of a difference between the scaling current measured in the total conductor line (4) and the sum of scaling current components measured in the at least two conduction paths (5), (6) that are connected in parallel, and wherein the scaling factors S₁, S₂ are only calculated as long as the scaling error lies below an adjustable scaling tolerance.

7. The method according to claim 1, characterized in that the scaling step takes place during start-up of the electrical circuit (1).

8. The method according to claim 1, characterized in that the current sensors (7), (8) each comprise a shunt.

9. The method according to claim 1, characterized in that the current sensor (9) comprises a Hall sensor.

10. A battery system comprising a battery and an electrical circuit (1) connected to the battery, the electrical circuit (1) including a total conductor section (2) and a parallel conductor section (3) connected in series with the total conductor section (2), and the total conductor section (2) has a total conductor line (4) and the parallel conductor section (3) has at least two parallel conduction paths (5), (6), said at least two parallel conduction paths (5), (6) each having a current sensor (7), (8) for determining current components I₁. I₂, characterized in that the battery system has a current sensor (9) in the total conductor line (4) for determining a total current I that is delivered by the battery and wherein a control device is furthermore provided, which is equipped to carry out a method according to claim 1.

11. The method according to claim 2, characterized in that the parallel conductor section (3) has exactly two parallel conduction paths (5), (6) and the monitoring takes place in such a way that no or a positive control message is emitted if the two calculated total currents I_{B1} (10), I_{B2} (11) and the measured total current I_{M} (12) are considered to be equally high.

12. The method according to claim 2, characterized in that the parallel conductor section (3) has exactly two parallel conduction paths (5), (6) and the monitoring takes place in such a way that a warning message is emitted if one of the compared currents I_{B1} (10), I_{B2} (11), I_{M} (12) deviates from at least one further compared current I_{B1} (10), I_{B2} (11), I_{M} (12).

13. The method according to claim 2, characterized in that the parallel conductor section (3) has exactly two parallel conduction paths (5), (6) and the monitoring takes place in such a way that the total current I in the total conductor line (4) is interrupted by an interruption device if all of the compared currents I_{B1} (10), I_{B2} (11), I_{M} (12) are not considered to be equally high.

14. The method according to claim 2, characterized in that the parallel conductor section (3) has exactly two parallel conduction paths (5), (6) and the monitoring takes place in such a way that an error message is emitted if all of the compared currents I_{B1} (10), I_{B2} (11), I_{M} (12) are not considered to be equally high.

15. The method according to claim 6, wherein the adjustable scaling tolerance is one ampere.

16. The battery system according to claim 10, wherein the battery is a lithium-ion battery.
